(19) United States
(12) Patent Application Publication
(10) Pub. No.: US 2006/0163713 A1
(43) Pub. Date: Jul. 27, 2006

(54) Semiconductor device

(75) Inventor: Shinya Tokunaga, Kyoto-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/335,514

(22) Filed: Jan. 20, 2006

(30) Foreign Application Priority Data
Jan. 25, 2005 (JP) P2005-016850

(51) Int. Cl. H01L 23/02

(52) U.S. Cl. 257/686; 439/66; 257/778; 257/E23.085

(57) ABSTRACT

In an SiP constituted by laminating a plurality of chips, it is an object to reduce a thickness of the SiP without damaging a strength of a chip on an upper side and deteriorating a reliability due to dicing in the case in which the chip on the upper side is larger than a chip on a lower side. A spot facing portion is provided by etching in the vicinity of a center of a bottom face of a chip on an upper side having a circuit formation surface to be a top face, and a chip on a lower side is disposed on an inside of the spot facing portion.

### BACKGROUND OF THE INVENTION

1. Field of the Invention

The present invention relates to a semiconductor device, and more particularly to an SiP (System in Package) technique for mounting a plurality of chips on the same package to constitute the semiconductor device, and at the same time, maintaining a strength and reducing a thickness, and decreasing a size thereof to be an almost chip size.

2. Description of the Related Art

With an increase in a density of the semiconductor device on a printed circuit board, a size of the semiconductor device has been reduced. In recent years, there has been developed a semiconductor device having a size reduced to be an almost chip size. In order to meet a demand for a reduction in the size, there has been proposed an SiP (System in Package) technique for mounting a system as one package.

As a technique for implementing the SiP, JP-A-11-204720 Publication (see FIG. 3) has proposed a semiconductor device in which another semiconductor chip is laminated on a surface at an opposite side to a circuit formation surface of a semiconductor chip mounted facedown on a substrate in such a manner that the circuit formation surface is placed on an upper side.

In the semiconductor device thus constituted, there is a problem in that a thickness of the whole SiP is increased because of the superposition of chips. Therefore, means for reducing a thickness of the semiconductor chip itself is used to reduce a whole thickness. As a result, recently, a conventional thickness of approximately 350 μm has been equal to or smaller than 100 μm.

In such a situation, in the case in which thin semiconductor chips having different sizes are superposed on each other, particularly, there is a problem in that a strength of the larger semiconductor chip cannot be maintained. As a method of solving the problem, a support table is provided on the larger semiconductor chip. However, the support table has a height of approximately 100 μm. For this reason, it is really hard to provide the support table.

As another method, there has been proposed a method of providing a spot facing portion on a back face of a semiconductor chip on an upper side and disposing the semiconductor chip on an inside of the spot facing portion (see JP-A-2003-86734 Publication (see FIG. 1)).

In the technique described in the Patent Document 2, a thickness can be reduced. In the case in which a spot facing portion is actually provided, however, it is hard to carry out formation. If the back face of the semiconductor chip is to be mechanically processed by a dicing blade to reduce a thickness of the semiconductor chip, there is a problem in that a reliability is deteriorated by a damage generated on a wafer (chip) by the dicing blade in a grinding method. Moreover, it is difficult to implement a mass production in respect of precision in a processing and a time required for the processing.

In the case in which the Patent Document 2 is applied, moreover, it is hard to uniformly fill a sealing resin in the spot facing portion even if the chip is to be sealed with the sealing resin. In particular, it is also apparent that there is a problem in that the sealing resin reaches rectangular portions on four corners in the spot facing portion with difficulty and a sufficient reliability cannot be obtained in respect of a mechanical strength and a sealing property.

### SUMMARY OF THE INVENTION

In consideration of the actual circumstances, it is an object of the invention to provide a semiconductor device having high precision in a processing, a small thickness and a high reliability.

In order to solve the problems, the invention provides a semiconductor device comprising a first semiconductor substrate, a second semiconductor substrate and an external connecting terminal connected to the first or second semiconductor substrate, wherein at least a part of the first semiconductor substrate is accommodated in a concave portion formed by anisotropic etching on a surface of the second semiconductor substrate.

According to the structure, the concave portion of the second semiconductor substrate positioned on an upper side is formed by anisotropic etching. Therefore, it is possible to form the concave portion with high precision without a strain. Consequently, it is possible to carry out bonding with high precision and to reduce a thickness more greatly.

Moreover, the invention provides the semiconductor device, wherein the second semiconductor substrate is provided with the concave portion in such a manner that at least a part of a peripheral part thereof is thicker than the other portions.

According to the structure, an opening of the concave portion is more increased in a peripheral part. Consequently, it is possible to easily bond the second and first semiconductor substrates.

The invention provides the semiconductor device, wherein the concave portion is formed by a bottom face which is parallel with a main surface of the second semiconductor substrate and a side surface surrounding the bottom face, and the side surface is an inclined face.

According to the structure, it is possible to easily fill an adhesive layer for bonding the first and second semiconductor substrates. Consequently, it is possible to carry out the bonding with a high reliability.

Furthermore, the invention provides the semiconductor device, wherein the inclined face is a predetermined crystal face.

According to the structure, it is possible to carry out a processing with high precision by utilizing an etching anisotropy of a crystal.

In addition, the invention provides the semiconductor device, wherein the first semiconductor substrate is fixed to the concave portion of the second semiconductor substrate through an adhesive layer.

According to the structure, also in the case in which the bonding is to be carried out by using the adhesive layer, the adhesive layer can be filled well so that the bonding can be carried out with a high reliability.

Moreover, the invention provides the semiconductor device, wherein a plurality of concave portions is formed on the second semiconductor substrate and the first semiconductor substrates are fixed to the concave portions one by one.

According to the structure, it is possible to easily form SiP mounting a large number of semiconductor substrates thereon.

Furthermore, the invention provides the semiconductor device, wherein the second semiconductor substrate is a silicon substrate and the inclined face is a {111} plane.

In the case in which etching is to be carried out by using an etchant such as KOH, an etching speed of a {111} plane is much lower than etching speeds of the other surfaces. As a result, therefore, the etching progresses in such a manner that the {111} plane is exposed. A {100} plane and the {111} plane have a positional relationship of 54.7 degrees. Accordingly, precision in the etching is very high so that a pattern with high precision can be obtained. Moreover, a main surface of the silicon substrate is set to be the {100} plane so that an inclined surface forming an angle of 54.7 degrees with the {111} plane is formed with high precision. The inclined surface is preferable for an attachment of the first semiconductor substrate. Moreover, the angle is exactly suitable for filling the adhesive resin.

In addition, the invention provides the semiconductor device, wherein the first semiconductor substrate is a first chip which is laminated and connected onto an interposer and has a circuit portion on a bottom face, and the second semiconductor substrate is a second chip mounted on the first chip to cover at least a part of the first chip.

According to the structure, it is possible to provide a semiconductor device having a small thickness and a high reliability.

Moreover, the invention provides the semiconductor device, wherein the second chip is connected to the interposer through a bonding wire, and the first and second chips are accommodated in a resin package together with the bonding wire.

According to the structure, since the first and second chips are accommodated in the resin package, they have a greater strength and a higher reliability.

Furthermore, the invention provides the semiconductor device, wherein the second chip has a height of a thick part of a spot facing portion from the interposer which is almost equal to that of the first chip from the interposer.

By the structure, terminal electrodes of the first and second chips can be fixed to the interposer with high precision and a reliable connection to the interposer can be carried out so that it is possible to perform mounting with a high reliability.

In addition, the invention provides the semiconductor device, wherein the second chip has a height of a thick part of a spot facing portion from the interposer which is greater than that of the first chip from the interposer.

Moreover, the invention provides the semiconductor device, wherein the first chip is disposed in such a manner that a center thereof is almost coincident with a center of the interposer, the second chip is disposed in such a manner that a center thereof is shifted from the center of the interposer, and a spot facing portion of the second chip is provided in a shifted position from the center of the second chip in such a manner that the first chip can be disposed on an inside of the spot facing portion.

Furthermore, the invention provides the semiconductor device, wherein the second chip has thick peripheral parts for all sides thereof.

In addition, the invention provides the semiconductor device, wherein the second chip has at least one of sides which is shorter than a side in the same direction in the first chip.

Moreover, the invention provides the semiconductor device, further comprising a third chip laminated on the interposer and having a circuit portion on a bottom face, the second chip being provided with another spot facing portion which is different from the spot facing portion, and the third chip having at least a part disposed on an inside of the another spot facing portion.

Furthermore, the invention provides the semiconductor device, wherein a trench portion is provided in such a manner that a height of at least a partial region in a thick part of a spot facing portion from the interposer is greater than a height of the first chip from the interposer.

In addition, the invention provides the semiconductor device, wherein the trench portion is uniformly provided on each side of a peripheral part of the spot facing portion.

Moreover, the invention provides the semiconductor device, wherein a plurality of trench portions is provided and has at least two depths.

Furthermore, the invention provides the semiconductor device, wherein the first semiconductor substrate is a first chip having a circuit portion on the concave portion side, the second semiconductor substrate is a second chip covering at least a part of the first chip and laminated and connected onto the interposer, and the first chip is directly connected to the second chip in the concave portion and is connected to the interposer through the second chip.

According to the semiconductor device in accordance with the invention, in the case in which the semiconductor chip provided on an upper side is larger than that provided on a lower side, the peripheral part of the semiconductor chip on the upper side is thick so that a strength thereof can be maintained to be high. Moreover, an extra member is not required and the periphery of the semiconductor chip on the upper side can be supported. Furthermore, the spot facing portion is generated by using the anisotropic etching. Therefore, it is possible to eliminate a bad influence on a reliability by a wafer (chip) damage generated by dicing. Consequently, a thickness can be reduced more greatly. Furthermore, precision in a processing and a time required for the processing can also be enhanced so that a mass production can be carried out.

### BRIEF DESCRIPTION OF THE DRAWINGS

FIG. 1(a) is a view showing a semiconductor device according to a first embodiment as seen from above and FIG. 1(b) is a sectional view showing the semiconductor device according to the first embodiment,

FIG. 2(a) is a sectional view showing a state brought before resin sealing of the semiconductor device according to the first embodiment,

FIG. 3 is a sectional view showing a process for manufacturing the semiconductor device,

FIG. 4 is a sectional view showing a semiconductor device according to a variant of the first embodiment,

FIG. 5(a) is a view showing a semiconductor device according to a second embodiment as seen from above and FIG. 5(b) is a sectional view showing the semiconductor device according to the second embodiment,

FIG. 6 is a view showing a semiconductor device according to a variant of the second embodiment as seen from above,

FIG. 7(a) is a view showing a semiconductor device according to a variant of the second embodiment as seen from above and FIG. 7(b) is a sectional view showing the semiconductor device according to the variant of the second embodiment,

FIG. 8(a) is a view showing a semiconductor device according to a variant as seen from above and FIG. 8(b) is a sectional view showing the semiconductor device according to the variant,

FIG. 9(a) is a view showing a semiconductor device according to a variant as seen from above and FIG. 9(b) is a sectional view showing the semiconductor device according to the variant,

FIG. 10(a) is a view showing a semiconductor device according to a variant as seen from above and FIG. 10(b) is a sectional view showing the semiconductor device according to the variant,

FIG. 11(a) is a view showing a semiconductor device according to a variant as seen from above and FIG. 11(b) is a sectional view showing the semiconductor device according to the variant,

FIG. 12(a) is a view showing a semiconductor device according to a variant as seen from above and FIG. 12(b) is a sectional view showing the semiconductor device according to the variant, and

FIG. 13(a) is a view showing a semiconductor device according to a third embodiment as seen from above and FIG. 13(b) is a sectional view showing the semiconductor device.

### DESCRIPTION OF THE PREFERRED EMBODIMENTS

### First Embodiment

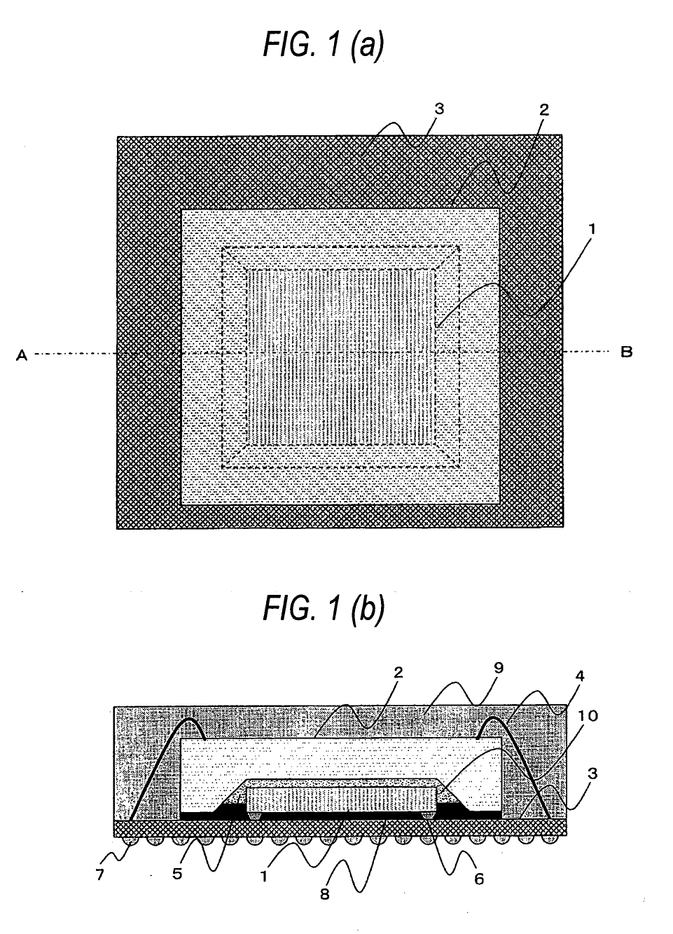

A first embodiment of the invention will be described below with reference to the drawings. FIG. 1(a) is a view showing a semiconductor device according to a first embodiment of the invention as seen from above and FIG. 1(b) is a sectional view taken along A-B thereof.

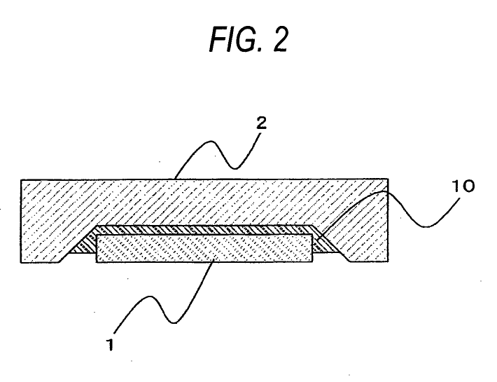

FIGS. 1(a) and (b) and FIG. 2 show a state brought before resin sealing. The semiconductor device according to the embodiment is characterized in that a first semiconductor chip 1 to be a first semiconductor substrate is accommodated in a concave portion (a spot facing portion) 10 formed on a surface of a second semiconductor chip 2 to be a second semiconductor substrate by anisotropic etching. 8 denotes an underfill and 9 denotes a sealing resin.

Both the first semiconductor chip 1 and the second semiconductor chip 2 constitute circuit formation surfaces on opposed surfaces to bonded surfaces, and the second semiconductor chip 2 is connected to an interposer 3 through a bonding wire 4 from the circuit formation surface. The interposer 3 is constituted by a flexible substrate having a multilayer structure provided with a wiring layer, and is connected to the first semiconductor chip 1 through a bump 6 provided on the first semiconductor chip 1 and the wiring layer and is connected to the second semiconductor chip 2 through the bonding wire 4.

A large number of solder balls are arranged on an opposed surface side of the interposer 3 so that a connection to a printed board (not shown) can be achieved.

There are provided the first semiconductor chip 1, the second semiconductor chip 2 provided with the spot facing portion 10 on a back face of the circuit formation surface, the interposer 3 to be the wiring layer, the bonding wire 4 for connecting the second semiconductor chip 2 to the interposer 3, a sealing resin 5, the bump 6 for connecting the first semiconductor chip 1 to the printed board, and an external terminal 7 for mounting which is formed by a solder ball constituting a ball grid array (BGA) for connecting the semiconductor device to the printed board.

In other words, the first semiconductor chip 1 is mounted on the interposer 3 with the circuit formation surface placed on a lower side (facedown). An electrical connection of the first semiconductor chip 1 and the interposer 3 is carried out through the bump 6. The second semiconductor chip 2 is provided with the spot facing portion 10 through anisotropic etching in such a manner that the back face of the circuit formation surface takes a concave shape. The second semiconductor chip 2 is mounted on the interposer 3 in such a manner that the circuit formation surface is placed on an upper side. An electrical connection of the second semiconductor chip 2 and the interposer 3 is carried out through the wire bonding 4.

The first semiconductor chip 1 is disposed on an inside of the spot facing portion 10 in the second semiconductor chip 2. As a result, a top face of the first semiconductor chip 1 supports the spot facing portion 10 in the second semiconductor chip 2 vertically from below through the sealing resin 5. The sealing resin 5 also functions as a buffer material. When the second semiconductor chip 2 is mounted on the interposer 3, moreover, a height of a thick peripheral part of the second semiconductor chip 2 from the interposer 3 is set to be almost equal to that of the first semiconductor chip 1 from the interposer 3. Consequently, the peripheral part of the second semiconductor chip 2 also serves as a support table.

The spot facing portion 10 in the second semiconductor chip 2 is formed by anisotropic etching or a combination of isotropic etching and the anisotropic etching. The anisotropic etching implies etching to be carried out on a condition that an etching speed in a specific direction is sufficiently higher than etching speeds in the other directions, and a formation surface can be finished more smoothly as compared with that in formation to be carried out through grinding. For example, the anisotropic etching is implemented by dry etching using reactive ion etching in a plasma, for example. In the case in which the isotropic etching and the anisotropic etching are combined with each other, the second semiconductor chip 2 may be first ground roughly by the isotropic etching and may be then finished to take a desirable shape by the anisotropic etching.

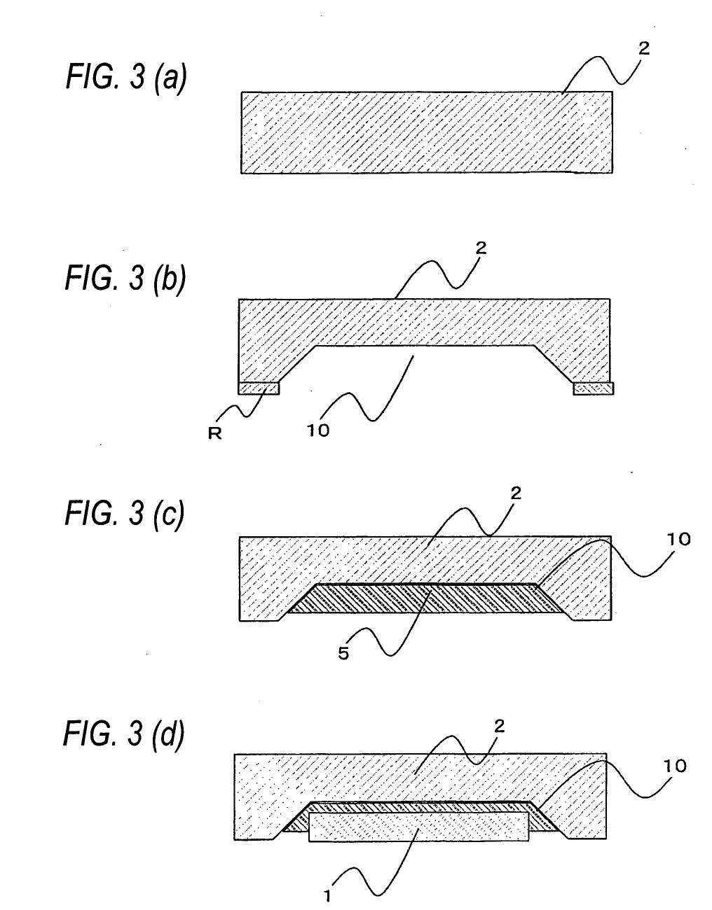

As shown in FIGS. 3(a) to 3(d), next, description will be given to a step of forming the spot facing portion through the anisotropic etching to be a main step and a step of bonding the first and second semiconductor chips in a process for manufacturing a semiconductor device.

First of all, as shown in FIG. 3(a), there is prepared a silicon substrate having a desirable circuit formed on a top face (a circuit portion is covered with a resist if necessary).

Then, a resist pattern R is formed on an opposed surface side to the circuit formation surface. The resist pattern R is used as a mask to form the spot facing portion 10 by wet etching using KOH as shown in FIG. 3(b). At this time, the circuit formation surface is set to be a {100} surface to carry out the etching. In the case in which the etching is to be carried out by using the KOH, silicon has an etching speed on a {111} surface which is much lower than etching speeds on the other surfaces. As a result, the etching progresses in such a manner that the {111} surface is exposed. The {100} surface and the {111} surface have a positional relationship of 54.7 degrees. When the {111} surface is exposed, accordingly, the etching is stopped. Consequently, precision in the etching is very high so that a pattern with high precision can be obtained. Thus, the main surface of the silicon substrate is set to be the {100} surface so that an inclined surface forming an angle of 54.7 degrees with respect to the {111} surface is formed with high precision.

The sealing resin 5 to be an adhesive resin is filled in the spot facing portion as shown in FIG. 3(c), and furthermore, the first semiconductor chip 1 is attached as shown in FIG. 3(d).

The inclined surface is preferable for attaching the first semiconductor chip 1 and forms an angle which is exactly suitable for filling the sealing resin 5 to be the adhesive resin.

Thus, a side surface of the spot facing portion 10 is formed to have a gradient in a vertical direction. The gradient is preferably approximately 30 to 60 degrees and is more preferably 45 to 55 degrees. When sealing is to be thus carried out with the sealing resin 5, the sealing resin 5 can smoothly enter an inner part so that unfilling of the sealing resin 5 can be lessened.

Then, a fixation to the interposer 3 provided with the BGA (external connecting terminal 7) is carried out through the underfill 8, and furthermore, the wire bonding is performed. Finally, resin sealing is carried out by using the sealing resin 9.

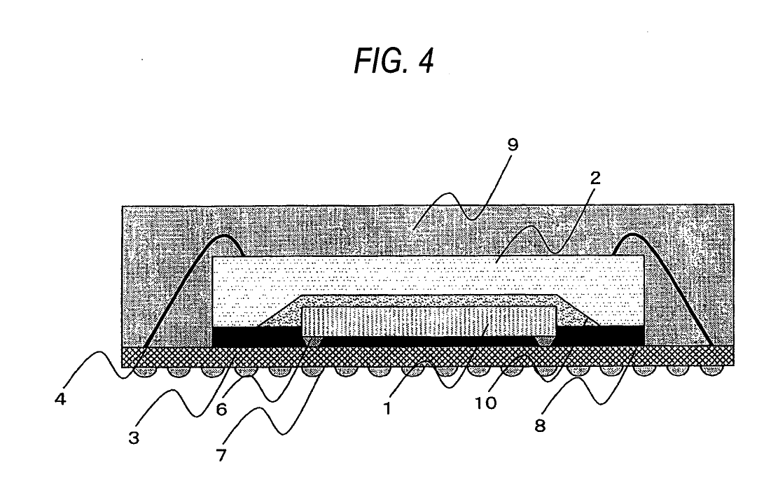

The thick peripheral part of the second semiconductor chip 2 may be constituted to have a greater height from the interposer 3 than a height of the first semiconductor chip 1 from the interposer 3 when the second semiconductor chip 2 is to be flipped and mounted on the interposer 3 as shown in FIG. 4. Consequently, the sealing resin can be filled more easily. By filling the underfill 8 in the clearance, it is possible to carry out a stronger fixation.

In the semiconductor device according to the first embodiment having such a structure, the peripheral part of the second semiconductor chip 2 is thick so that a strength thereof can be maintained to be great. Moreover, an extra member is not required and the periphery of the second semiconductor chip can be supported. Furthermore, it is possible to eliminate a bad influence on a reliability which is caused by a wafer (chip) damage generated due to dicing. In addition, it is possible to uniformly spread the sealing resin.

While the electrical connection of the second semiconductor chip is carried out through the wire bonding in the first embodiment, an external connection may be implemented through the first semiconductor chip 1 or the second semiconductor chip may be taken out to an opposed surface side via a through hole or a region having a high concentration. This example will be described below.

### Second Embodiment

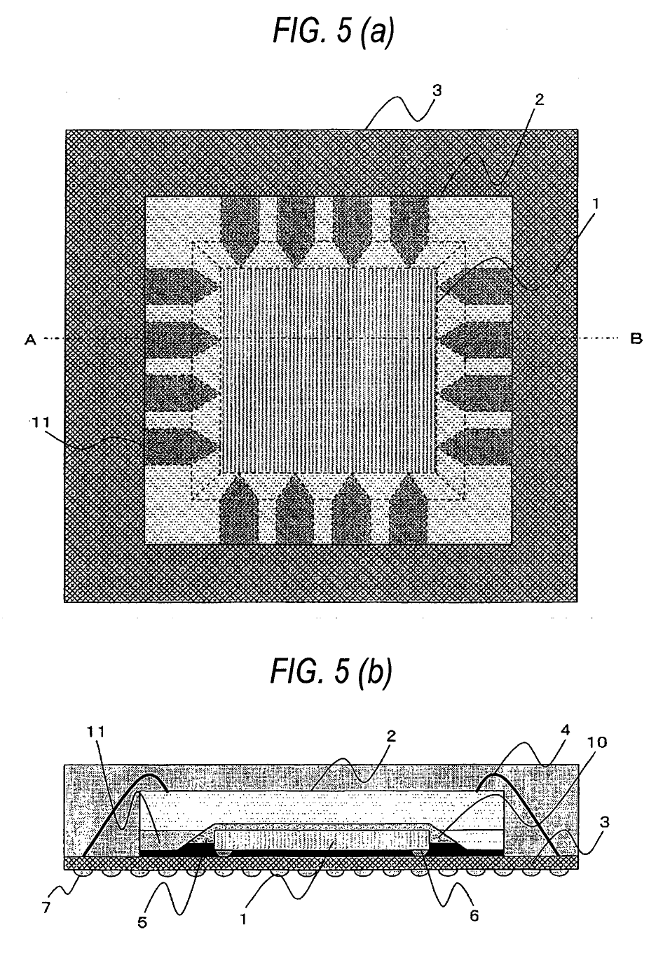

A second embodiment of the invention will be described below with reference to the drawings. FIG. 5(a) is a view showing a semiconductor device according to the second embodiment of the invention as seen from above and FIG. 5(b) is a sectional view taken along A-B in FIG. 5(a). The same components as those in the first embodiment have the same reference numerals and description will be omitted.

The second embodiment is different from the first embodiment in that a trench portion 11 is provided around a second semiconductor chip 2 in order to form a passage for a sealing resin in such a manner that resin sealing can easily be carried out. The trench portion 11 is provided uniformly on each side of the second semiconductor chip 2 and perpendicularly to each side, and a sealing resin 5 is caused to enter through the trench portion 11 so that the sealing resin 5 can be filled uniformly in order to eliminate an unfilled place.

The trench portion 11 is also formed by anisotropic etching or a combination of isotropic etching and the anisotropic etching in the same manner as a spot facing portion 10.

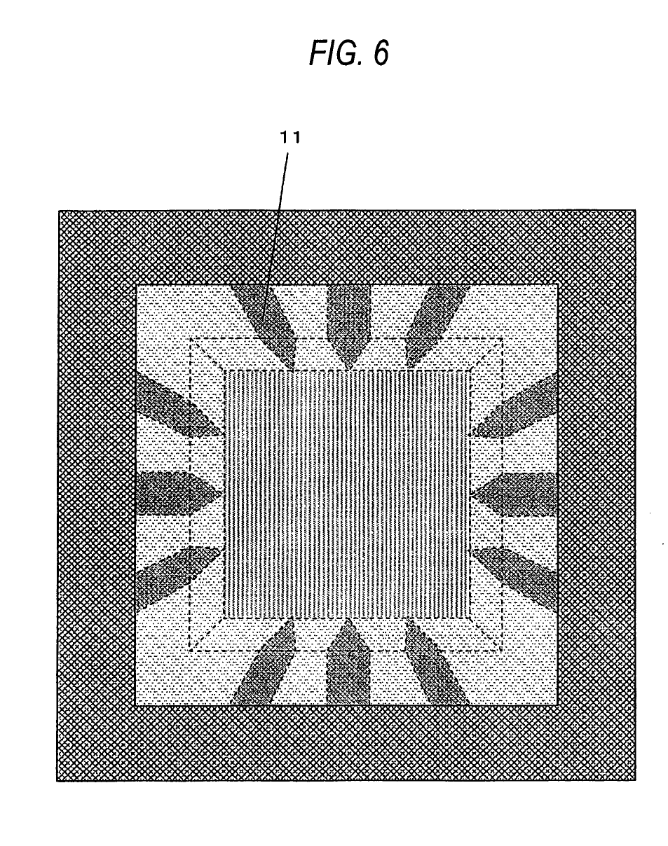

The trench portions 11 may be constituted radially to be turned toward a center of the second semiconductor chip 2 as shown in FIG. 6.

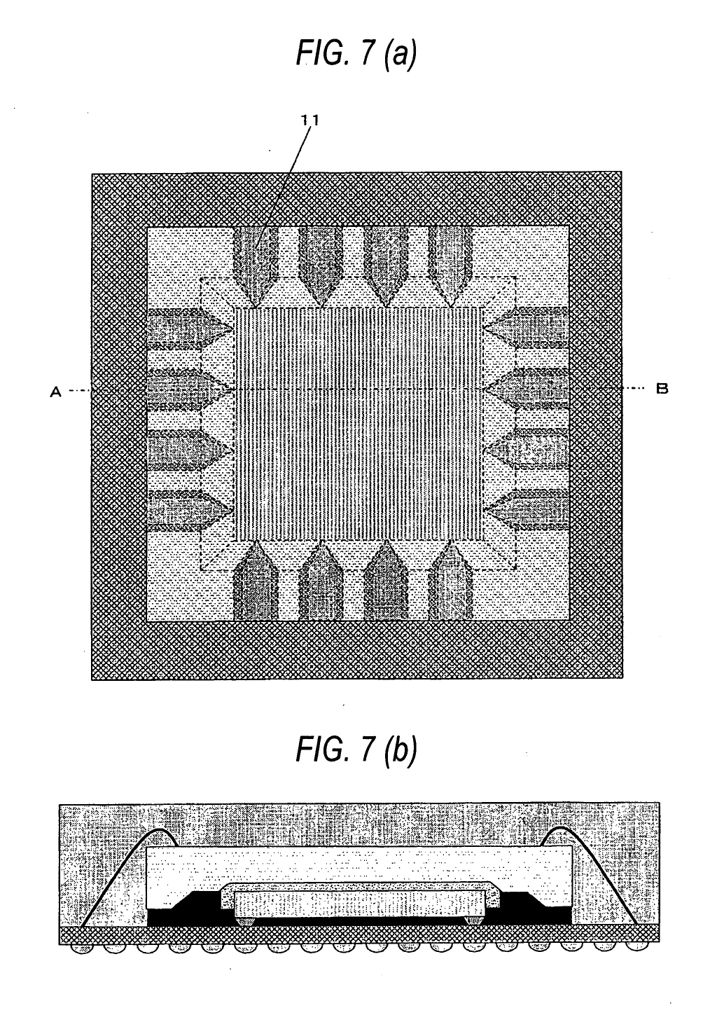

Moreover, the trench portion 11 may have two depths or more as shown in FIGS. 7(a) and (b). Consequently, the filling can be carried out more easily.

The semiconductor device according to the second embodiment has the same advantages as those in the first embodiment. As compared with the first embodiment, moreover, the resin sealing can be carried out more easily and the unfilled place can be eliminated.

(Variant)

While the two embodiments to be the basis of the invention have been described above, the invention can be modified without departing from the scope of the invention.

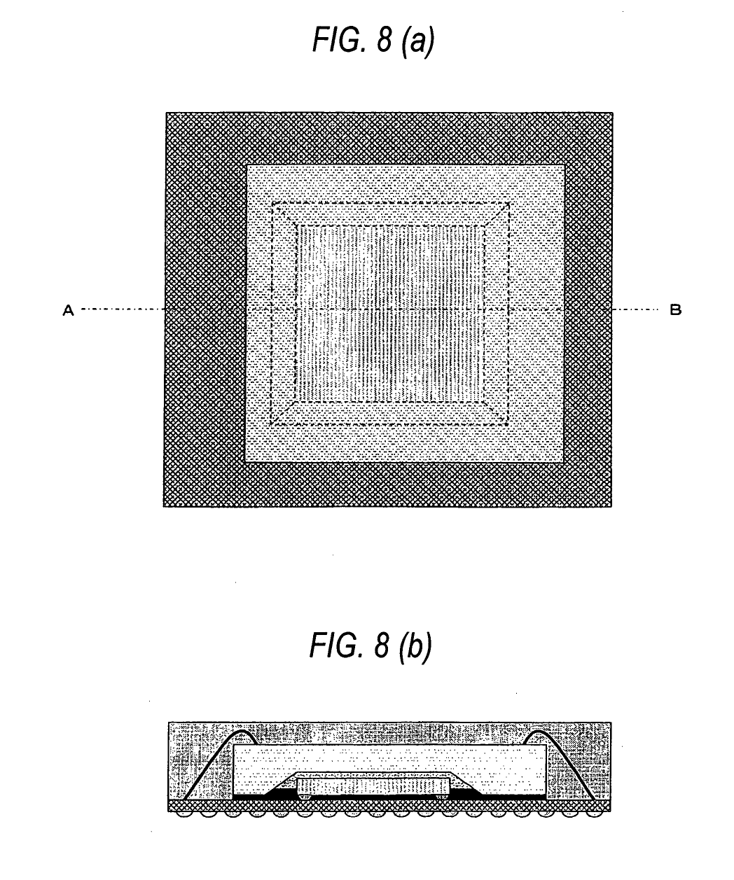

For example, as shown in FIGS. 8(a) and (b), centers of a first semiconductor chip 1 and a second semiconductor chip 2 do not need to be always coincident with a center of an interposer 3. For example, as shown in FIGS. 8(a) and (b), it is also possible to employ a structure in which the center of the first semiconductor chip 1 is almost coincident with that of the interposer 3, the center of the second semiconductor chip 2 is shifted from that of the interposer 3, and a center of a spot facing portion 10 of the second semiconductor chip 2 is provided in a shift position from that of the second semiconductor chip 2 in such a manner that the first semiconductor chip 1 can be disposed on an inside of the spot facing portion 10.

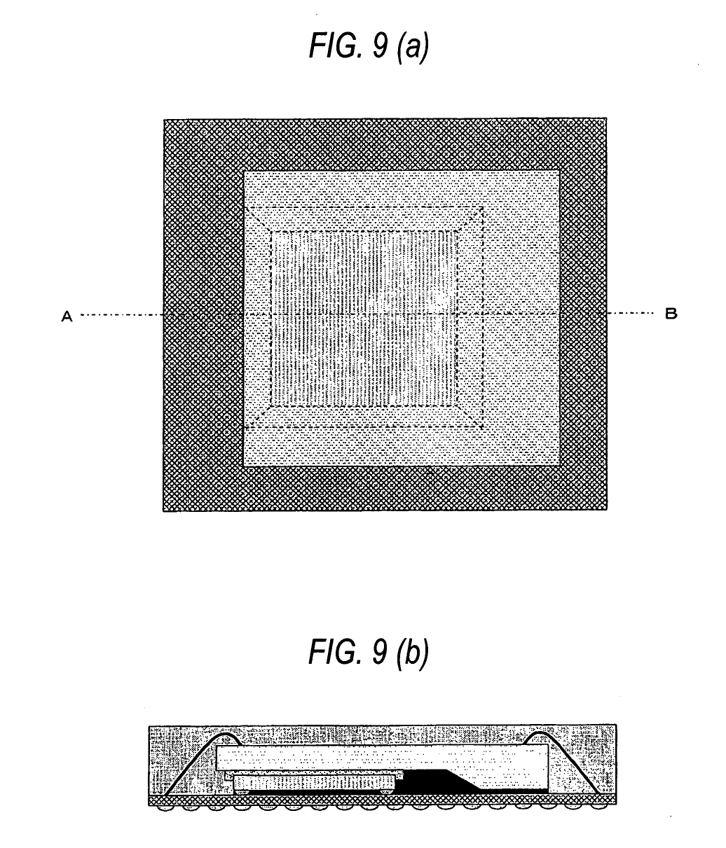

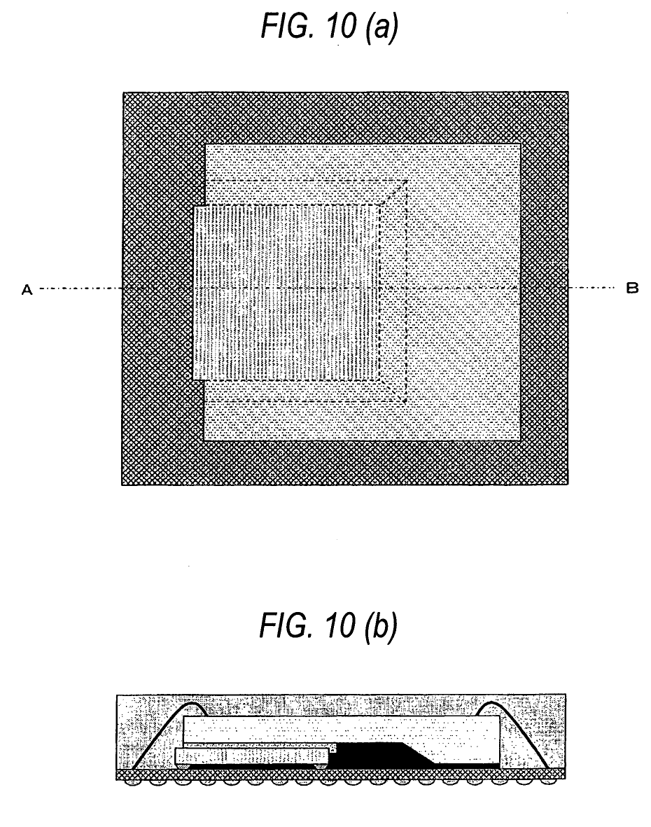

Moreover, the spot facing portion 10 provided in the second semiconductor chip 2 does not need to be completely provided on the inside of the second semiconductor chip 2. For example, the spot facing portion 10 may be provided so as not to leave a thickness on a periphery of any of sides as shown in FIGS. 9(a) and (b) depending on circuit layouts of the first semiconductor chip 1 and the second semiconductor chip 2. In that case, the first semiconductor chip 1 does not need to be perfectly disposed on the inside of the second semiconductor chip 2 but may be protruded in a certain direction as shown in FIGS. 10(a) and (b).

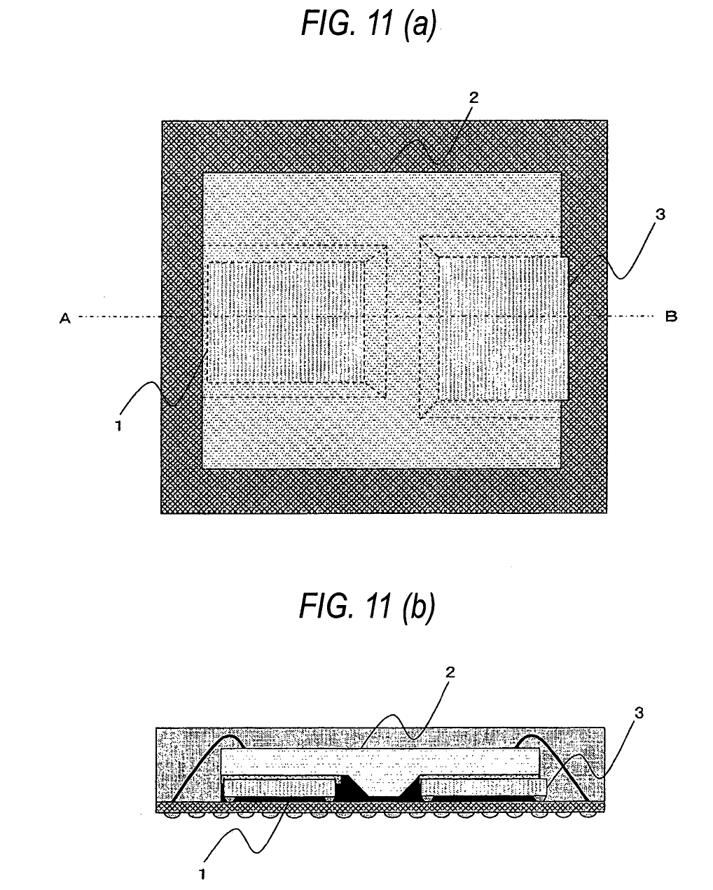

Moreover, the first semiconductor chip 1 and a third semiconductor chip 30 may be disposed under the second semiconductor chip 2 as shown in FIGS. 11(a) and (b). In FIGS. 11(a) and (b), the first semiconductor chip 1 is included in the second semiconductor chip 2 and the third semiconductor chip 30 is protruded from the second semiconductor chip 2 in one direction.

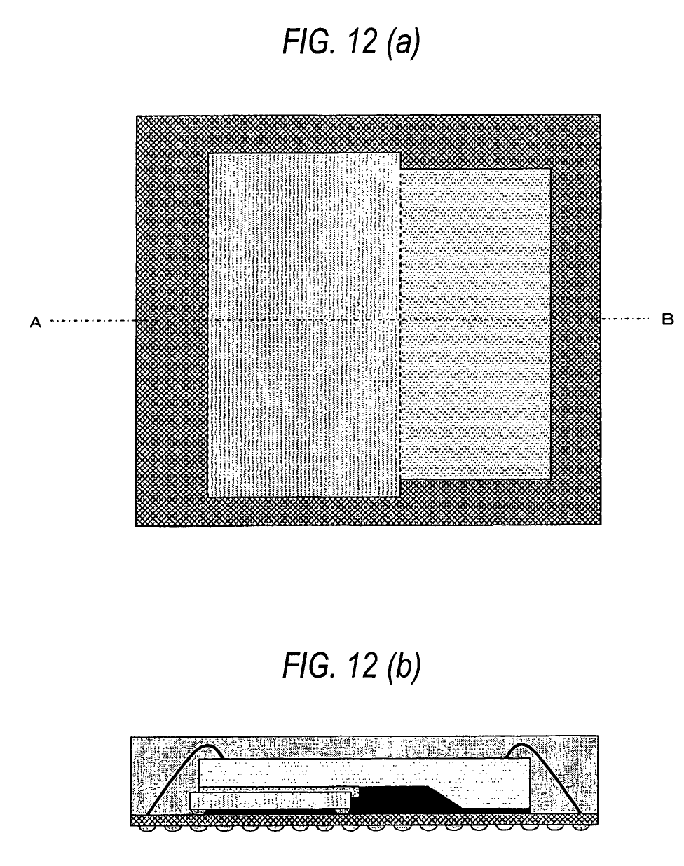

As shown in FIGS. 12(a) and (b), moreover, the second semiconductor chip 2 may have at least one of sides which is shorter than the first semiconductor chip 1.

As shown in the above variant, any spot facing portion to be provided on the second semiconductor chip is determined optimally depending on a relationship between the sizes of the first semiconductor chip and the second semiconductor chip, a circuit layout or positions of a pad and a bump.

### Third Embodiment

While the description has been given to the example in which the wiring, bonding is used, a second semiconductor chip 2 may be directly connected to an interposer 3 so as to be taken out.

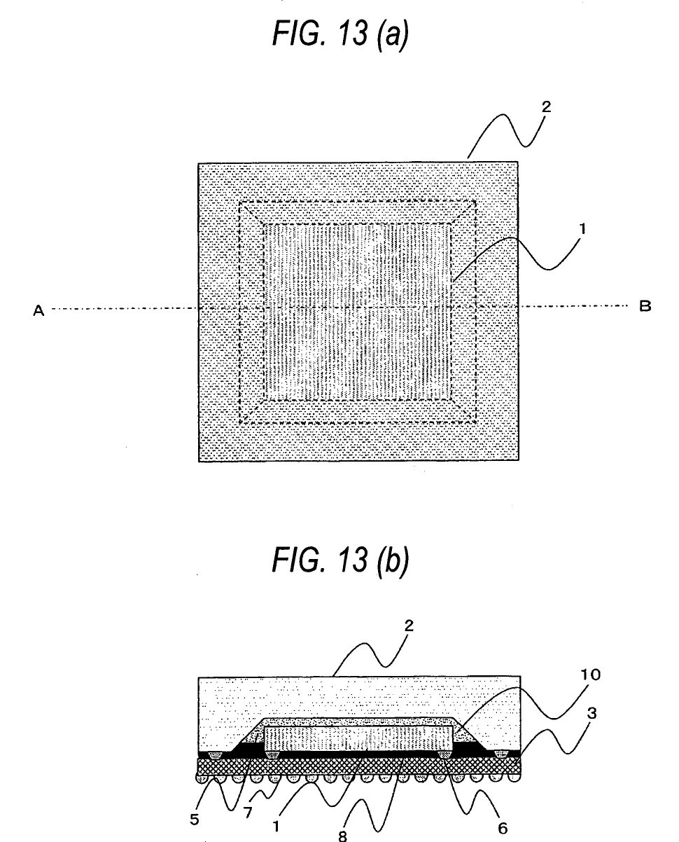

This example is shown in FIGS. 13(a) and (b). More specifically, the second semiconductor chip 2 is taken out on the interposer side and direct bonding to the interposer 3 is carried out through a bump 6.

The outside may be subjected to resin sealing or a bare chip may be maintained. Consequently, it is possible to implement a great reduction in a size.

In this case, moreover, it is also possible to carry out the bonding and the formation of the bump on a wafer level and to subsequently perform dicing for a division into individual semiconductor chips. Consequently, manufacture can be carried out very easily.

Furthermore, a circuit formation surface of the second semiconductor chip 2 may be placed on a first semiconductor chip 1 side and a connection may be carried out in a spot facing portion through direct bonding. In this case, the second semiconductor chip 2 may be taken out through the first semiconductor chip 1.

The first and second semiconductor chips may be formed by silicon substrates of the same type, silicon substrates of reverse conductivity types to each other, or silicon substrates of the same conductivity type having different carrier concentrations. Furthermore, the first semiconductor chip may be constituted by a compound semiconductor and the second semiconductor chip may be constituted by silicon.

According to the invention, it is possible to implement an SiP having a great strength, a high reliability and a small thickness. Consequently, the invention can be applied to a small-sized product such as a cell phone.

What is claimed is:

1. A semiconductor device, comprising:
a first semiconductor substrate;
a second semiconductor substrate; and
an external connecting terminal, connected to the first or second semiconductor substrate;
wherein at least a part of the first semiconductor substrate is accommodated in a concave portion formed by anisotropic etching on a surface of the second semiconductor substrate.

2. The semiconductor device according to claim 1, wherein the second semiconductor substrate is provided with the concave portion in such a manner that at least a part of a peripheral part thereof is thicker than the other portions.

3. The semiconductor device according to claim 1, wherein the concave portion is formed by a bottom face which is parallel with a main surface of the second semiconductor substrate and a side surface surrounding the bottom face, and the side surface is an inclined face.

4. The semiconductor device according to claim 3, wherein the inclined face is a predetermined crystal face.

5. The semiconductor device according to claim 1, wherein the first semiconductor substrate is fixed to the concave portion of the second semiconductor substrate through an adhesive layer.

6. The semiconductor device according to claim 1, wherein a plurality of concave portions is formed on the second semiconductor substrate and the first semiconductor substrates are fixed to the concave portions one by one.

7. The semiconductor device according to claim 4, wherein the second semiconductor substrate is a silicon substrate and the inclined face is a {111} plane.

8. The semiconductor device according to claim 1, wherein the first semiconductor substrate is a first chip which is laminated and connected onto an interposer and has a circuit portion on a bottom face, and
the second semiconductor substrate is a second chip mounted on the first chip to cover at least a part of the first chip.

9. The semiconductor device according to claim 8, wherein the second chip is connected to the interposer through a bonding wire, and
the first and second chips are accommodated in a resin package together with the bonding wire.

10. The semiconductor device according to claim 9, wherein the second chip has a height of a thick part of a spot facing portion from the interposer which is almost equal to that of the first chip from the interposer.

11. The semiconductor device according to claim 9, wherein the second chip has a height of a thick part of a spot facing portion from the interposer which is greater than that of the first chip from the interposer.

12. The semiconductor device according to claim 9, wherein the first chip is disposed in such a manner that a center thereof is almost coincident with a center of the interposer;
the second chip is disposed in such a manner that a center thereof is shifted from the center of the interposer; and
a spot facing portion of the second chip is provided in a shifted position from the center of the second chip in such a manner that the first chip can be disposed on an inside of the spot facing portion.

13. The semiconductor device according to claim 9, wherein the second chip has thick peripheral parts for all sides thereof.

14. The semiconductor device according to claim 9, wherein the second chip has at least one of sides which is shorter than a side in the same direction in the first chip.

15. The semiconductor device according to claim 9, further comprising:
a third chip, laminated on the interposer and having a circuit portion on a bottom face, the second chip being provided with another spot facing portion which is different from the spot facing portion, and
the third chip having at least a part disposed on an inside of the another spot facing portion.

16. The semiconductor device according to claim 9, wherein a trench portion is provided in such a manner that a height of at least a partial region in a thick part of a spot facing portion from the interposer is greater than a height of the first chip from the interposer.

17. The semiconductor device according to claim 16, wherein the trench portion is uniformly provided on each side of a peripheral part of the spot facing portion.

18. The semiconductor device according to claim 16, wherein a plurality of trench portions is provided and has at least two depths.

19. The semiconductor device according to claim 8, wherein the first semiconductor substrate is a first chip having a circuit portion on the concave portion side,
the second semiconductor substrate is a second chip covering at least a part of the first chip and laminated and connected onto the interposer, and
the first chip is directly connected to the second chip in the concave portion and is connected to the interposer through the second chip.
